(19) United States
(12) Patent Application Publication
(10) Pub. No.: US 2026/0298553 A1
(43) Pub. Date: Oct. 1, 2026

(54) HEAT EXCHANGE MECHANISM, PROCESSING DEVICE, AND PROCESSING MACHINE

(71) Applicant: HON. PRECISION, INC., Taichung City (TW)

(72) Inventor: Ching-Hsiang Yu, Taichung City (TW)

(21) Appl. No.: 19/404,389

(22) Filed: Dec. 1, 2025

(30) Foreign Application Priority Data
Mar. 25, 2025 (TW) 114111132

(51) Int. Cl. F28F 3/08; F28F 3/12; G01R 31/28; F28D 21/00

(52) U.S. Cl. CPC F28F 3/08; F28F 3/12; G01R 31/28; F28D 2021/0028; F28F 2260/02

(57) ABSTRACT

The heat exchanging mechanism includes a micro-channel unit and a temperature unit. The micro-channel unit has a base seat having a contact face. The base seat has plural inlets, plural micro-channels, and plural outlets therein. The fluid at a predetermined temperature is injected into the micro-channels from the inlets. The fluid exchanges heat with the contact face at the micro-channels. The heat-exchanged fluid is discharged via the outlets. The temperature unit has at least one temperature member at the base seat of the micro-channel unit. The temperature member makes the temperature of the contact face constant.

### FIELD OF THE INVENTION

The present disclosure relates to a heat exchange mechanism which is capable of heat exchanging in plural micro-areas so that the temperature can be controlled precisely.

### BACKGROUND OF THE INVENTION

Nowadays, the processing device is arranged with a pressing mechanism, a transportation mechanism, a pre-cooling/pre-heating mechanism, and others, to undergo a predetermined process at the predetermined temperature. For example, during the testing process under the low temperature, the testing mechanism has a testing member to receive and test the electronic component. The pressing mechanism is arranged above the testing member. The pressing mechanism has a pressing member and a flow channel seat. The pressing member is adapted for pressing and contacting the electronic component. The flow channel seat has a single flow channel therein. An end of the flow channel has an inlet for injecting the refrigerant. The refrigerant flows toward an outlet at the other end of the flow channel so that the pressing member has a predetermined low temperature to contact the electronic component and to control the temperature of the electronic component. Thus, a environment of operation can be simulated, and the electronic component can be tested under the predetermined low temperature.

However, the temperature of the flowing refrigerant may increase due to the heat exchange between the pressing member and the electronic component even though the temperature of the refrigerant at the inlet is low enough. Thus, the refrigerant flowing to the outlet is unable to maintain the predetermined low temperature. That is, the side of the bottom of the pressing member near the outlet is unable to have the predetermined low temperature. In other words, two sides of the bottom of the pressing member have different temperatures. The temperature of the electronic component cannot be controlled evenly so as to reduce the performance of testing of the electronic component.

The present invention is, therefore, arisen to obviate or at least mitigate the above mentioned disadvantages.

### SUMMARY OF THE INVENTION

One of the objects of the present invention is to provide a heat exchange mechanism including a micro-channel unit and a temperature unit. The micro-channel unit has a base seat with a contact face. The base seat is formed with a plurality of inlets, a plurality of micro-channels, and a plurality of outlets. The fluid is injected into the micro-channels from the inlets, and the fluid in the micro-channels exchanges heat with the contact face in plural micro-areas. The heat-exchanged fluid in the micro-channels is discharged via the outlets. The temperature unit has at least one temperature member in the base seat or/and at the micro-channels. The temperature member corresponds to the fluid in the micro-channels to make the temperature of the contact face constant. Thus, the heat consumption in the flowing channel can be prevented, and the contact area between the fluid and the contact face is increased so that the temperature can be controlled precisely.

Another one of the objects of the present invention is to provide a heat exchange mechanism having micro-section with plural layers so that the flow can be increased even when the length of the micro-channel doesn’t change. Thus, the performance of heat exchange is improved, and the temperature can be controlled precisely.

Another one of the objects of the present invention is to provide a processing device including at least one supporter, at least one heat exchange mechanism, and at least one processing member. The at least one heat exchange mechanism is arranged on the supporter and has a micro-channel unit and a temperature unit to control the temperature of the electronic component. The at least one processing member is arranged on the contact face of the heat exchange mechanism or is defined on the contact face. The processing member is adapted for undergoing a predetermined process on the electronic component.

Another one of the objects of the present invention is to provide a processing machine including a machine, a feeding device, a collecting device, a testing device, a processing device, and a central control device. The feeding device is arranged on the machine and has at least one feeding member to receive the electronic component to be tested. The collecting device is arranged on the machine and has at least one collecting member to receive the tested electronic component. The testing device is arranged on the machine and has at least one testing member to test the electronic component. The processing device is arranged on the machine and has at least one supporter, at least one heat exchange mechanism, and at least one processing member to control the temperature of the electronic component and to undergo the predetermined process on the electronic component. The central control device is adapted for controlling and integrating the devices to achieve the automatic process.

The present invention will become more obvious from the following description when taken in connection with the accompanying drawings, which show, for purpose of illustrations only, the preferred embodiment(s) in accordance with the present invention.

### BRIEF DESCRIPTION OF THE DRAWINGS

The present disclosure can be more fully understood by reading the following detailed description of the embodiment, with reference made to the accompanying drawings as follows:

FIG. 1 is an illustration showing a first embodiment of a heat exchange mechanism of the present invention;

FIG. 2 is an illustration showing a first embodiment of a processing device with a heat exchange mechanism of the present invention;

FIG. 3 to FIG. 5 are illustrations of a processing device during operation;

FIG. 6 is an illustration showing a second embodiment of a heat exchange mechanism of the present invention;

FIG. 7 is an illustration showing a second embodiment of a processing device of the present invention;

FIG. 8 is an illustration showing a processing machine of the present invention.

### DETAILED DESCRIPTION OF THE PREFERRED EMBODIMENTS

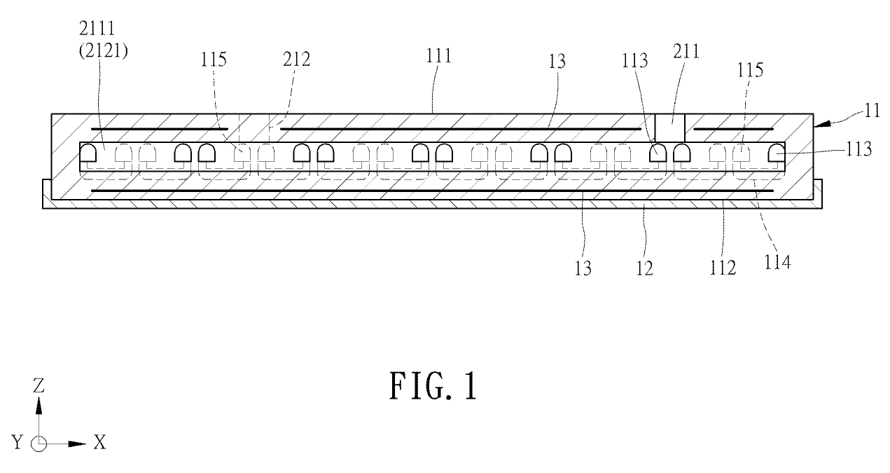

Please refer to FIG. 1 for the first embodiment of the heat exchange mechanism of the present invention. The heat exchange mechanism includes a micro-channel unit and a temperature unit.

The micro-channel unit has a base seat having an install face and a contact face. The base seat is formed with a plurality of inlets, a plurality of micro-channels, and a plurality of outlets. The fluid enters the micro-channels from the inlets, and the fluid exchanges heat with the contact face at the micro-channels in plural micro-areas. The heat-exchanged fluid is discharged from the micro-channels via the outlets.

Specifically, the base seat can be formed in a single piece or be composed of plural plates stacked together.

When the base seat is formed in a single piece, the first face (e.g. the top face) is defined as the install face, and the second face (e.g. the bottom face) opposite to the first face is defined as the contact face. The inlets, the micro-channels, and the outlets are formed inside the base seat.

When the base seat is composed of plural plates stacked together, the plates can include a first plate and a second plate. The second face (e.g. the bottom face) of the first plate is defined as the contact face, and the micro-channels are formed in the first plate. The first face (e.g. the top face) of the second plate is defined as the install face. The second face of the second plate is stacked onto the first face (e.g. the top face). The inlets and the outlets are formed in the second plate.

Specifically, the at least one temperature member of the temperature unit is arranged on one or plural ones of the first plate, the second plate, and the micro-channels.

In another embodiment, the plural plates of the base plate include a first plate, a second plate, and a third plate. The first plate is formed with the micro-channels penetrating the first face (e.g. the top face) and the second face (e.g. the bottom face). The first face (e.g. the top face) of the second plate is defined as the install face, and the second face of the second plate stacked onto the first face of the first plate. The second plate has the inlets and the outlets. The second face (e.g. the bottom face) of the third plate is defined as the contact face, and the first face of the third plate is stacked onto the second face of the first plate.

Specifically, the at least one temperature member of the temperature unit is arranged on one or plural ones of the second plate, the third plate, and the micro-channels.

In some embodiments, the heights of the micro-channels are different from the heights of the inlets and the outlets.

In some embodiments, the contact face of the micro-channel unit is arranged with at least protection member to enhance the structural strength of the contact face.

In some embodiments, the fluid can be refrigerant, liquid at low temperature, liquid at high temperature, or others.

In the present embodiment, the base seat 11 of the micro-channel unit is made of ceramics which is heat-conductive but electricity-non-conductive. The first face (e.g. the top face) of the base seat 11 is defined as the install face 111 to connect to at least one supporter (e.g. a moving arm, not shown in the drawings). The second face opposite to the first face of the base seat 11 is defined as the contact face 112 to press and contact the electronic component or to connect to at least one processing member (e.g. a pressing member, not shown in the drawings). The base seat 11 is formed with a plurality of inlets 113, a plurality of micro-channels 114, and a plurality of outlets 115 therein. The diameter of each of the inlets 113 is 0.2 mm, and the inlets 113 communicate a water inlet channel 211 and the micro-channels 114 in the base seat 11. In addition, the height of the inlet 113 is different from the height of the micro-channel 114. The inlet branch channels 2111 of the water inlet channel 211 communicate the inlets 113, so the fluid (e.g. the refrigerant) can be injected into the inlets 113 via the inlet branch channels 2111 from the water inlet channel 211. The micro-channels 114 are aligned at the area of the base seat 11 near the contact face 112. Each micro-channel 114 is arranged along the X-direction and has a length of 0.4 mm. An end of the micro-channel 114 communicates the inlet 113, and the other end communicates the outlet 115. The fluid is injected into the micro-channels 114 from the inlet 113 so that the fluid in the micro-channels 114 can exchange heat with the contact face 112 in plural micro-areas. Each outlet 115 has a diameter of 0.2 mm and communicates the micro-channel 114 and the water outlet channel 212 at the base seat 11. The height of the outlet 115 is different from the height of the micro-channel 114. The outlet branch channels 2121 of the water outlet channel 212 communicate the outlets 115. The heat-exchanged fluid from the micro-channels 114 enters the outlet branch channels 2121 via the outlets 115, and the fluid is further discharged from the water outlet channel 212.

Specifically, a protection member 12 made of metal can be arranged on the contact face 112 of the base seat 11 which is made of ceramics. The protection member 12 can increase the structural strength of the base seat 11 to be easier to press the electronic component and to control the temperature of the electronic component (not shown in drawings).

The inlets 113 communicate a single water inlet channel 211 to provide the fluid or plural water inlet channels 211 to provide them the fluid. The present invention is not limited by the present embodiment.

The outlets 114 communicate a single water outlet channel 212 to discharge the heat-exchanged fluid or plural water outlet channels 212 to discharge the fluid via the water outlet channels 212. The present invention is not limited by the present embodiment.

The temperature unit has at least one temperature member at the base seat 11 or/and the micro-channels 114 of the micro-channel unit. The temperature member makes the temperature of the contact face constant via the fluid in the micro-channels. Specifically, the temperature member can be a heating wire, a thermoelectric cooler, or others. The present invention is not limited by the present embodiment.

In some embodiments, at least one heating wire is arranged inside the wall of the base seat 11. The temperature of the heating wire corresponds to the temperature of the fluid so as to control the temperature of the contact face 112 at a predetermined temperature. In some embodiments, at least one heating wire is arranged at the micro-channels 114. A covering member covers the heating wire wherein the covering member is heat-conductive but electricity-non-conductive. Thus, when the heating wire is electrified, the temperature of the heating wire corresponds to the temperature of the fluid so as to control the temperature of the contact face 112 at a predetermined temperature. The present invention is not limited by the present embodiment.

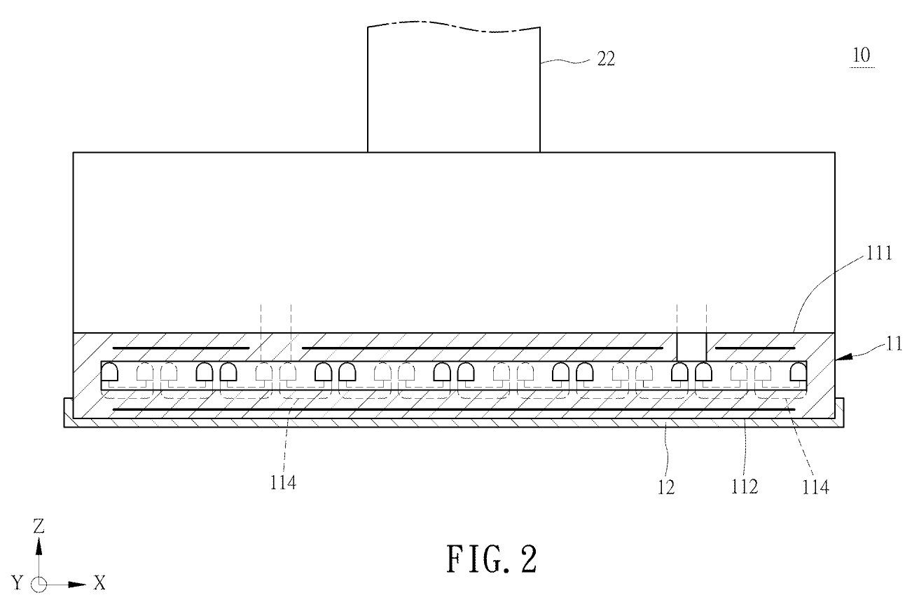

Please refer to FIG. 2, the processing device 10 of the present invention includes a supporter, at least one heat exchange mechanism, and at least one processing member. The supporter is adapted for the heat exchange mechanism to install on. The heat exchange mechanism includes a micro-channel unit and a temperature unit to control the temperature of the electronic component. The processing member is disposed on the contact face of the heat exchange mechanism or is defined on the contact face of the heat exchange mechanism. The processing member is adapted for undergoing a predetermined process on the electronic component.

Specifically, the supporter can be arranged fixedly or movably. For example, the supporter can be a rack, a platform, a fixing seat, or others, to install the heat exchange mechanism fixedly. For another example, the supporter is a moving arm, a moving seat, or others, which is movable along at least one direction, to drive the heat exchange mechanism to move along at least one direction.

Specifically, the processing member can be a contact face, a pressing member, a shifting member, a cooling/heating platform, a support platform, or others. The present invention is not limited by the present embodiment.

In the present embodiment, the supporter is a moving arm 22 which is driven to move along at least the Z-direction by the driving source (not shown in the drawings). The moving arm 22 is adapted for connecting to the install face 111 of the base seat 11 of the heat exchange mechanism so as to drive the heat exchange mechanism to move along the Z-direction. The contact face 112 of the base seat 11 of the heat exchange mechanism is defined as the processing member. The processing member is a pressing member too. That is, the contact face 112 can press and contact the electronic component. However, to enhance the structural strength of the contact face 112, the contact face 112 presses the electronic component (not shown in the drawings) and control the temperature of the electronic component via the protection member 12.

In other embodiments, a floating member (not shown in the drawings) can be arranged between the base seat 11 and the supporter for cushion.

Specifically, a temperature controlling member can be arranged on the top of the base seat 11 of the heat exchange mechanism, The temperature controlling member can be a thermoelectric cooler or a refrigerant device with refrigerant. For example, the fluid flowing into the micro-channels 114 of the heat exchange mechanism is a fluid at low temperature. The temperature controlling member is a refrigerant device with refrigerant. Thus, the fluid can be further cooled down to reach the predetermined temperature more quickly. The present invention is not limited by the present embodiment.

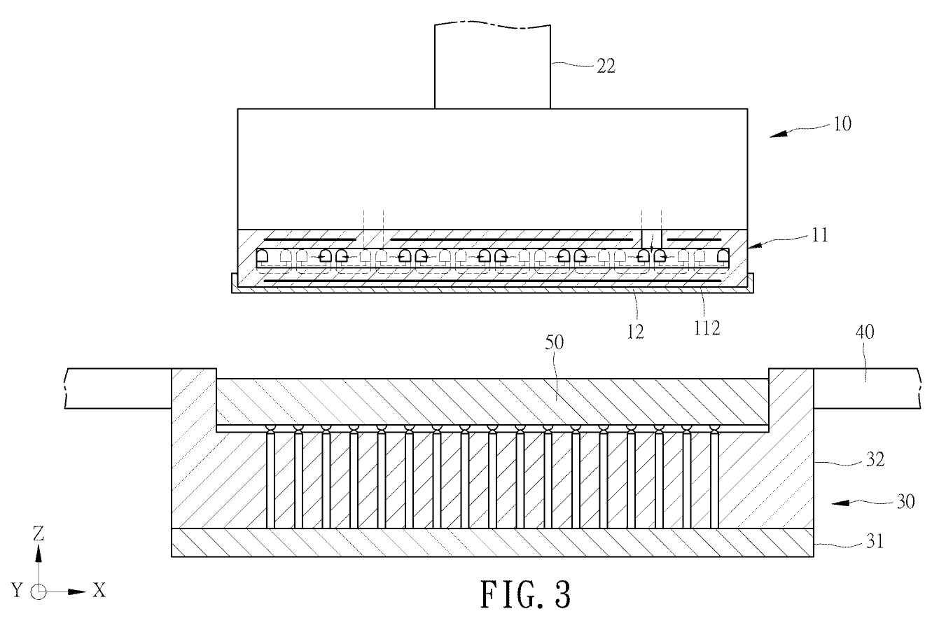

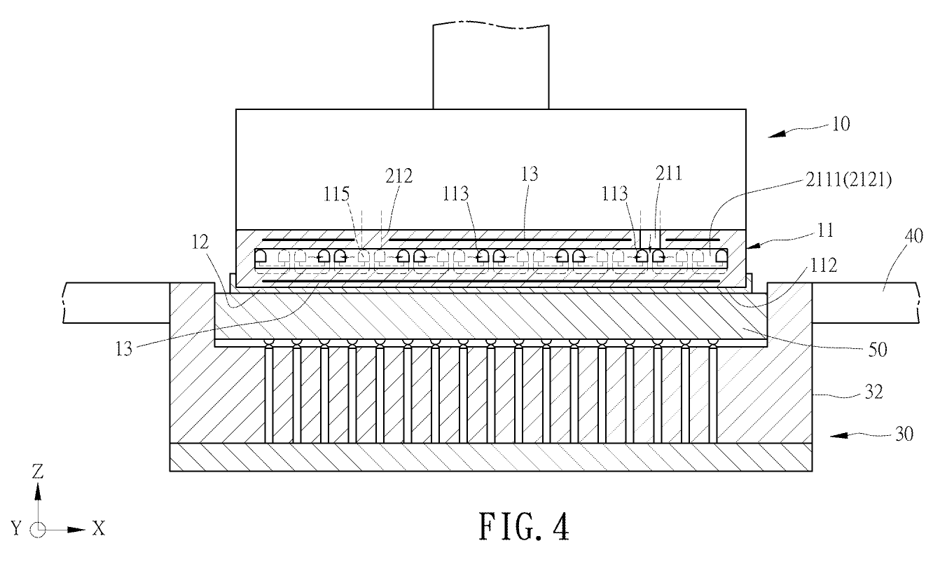

Please refer to FIG. 3 and FIG. 4 for the illustration showing the processing device 10 and the testing device 30 during operation. The testing device 30 is arranged on the machine 40 and has at least one testing member to test the electronic component. In the present embodiment, the testing member includes a circuit board 31 and a testing seat 32 which are electrically connected. The testing seat 32 is adapted for receiving and testing the electronic component. The processing device 10 is arranged above the testing seat 32. The base seat 11, the contact 112, and the protection member 12 of the heat exchange mechanism are driven to move toward the testing member 32 and the electronic component 50 along the Z-direction by the moving arm 22.

During the testing process under the low temperature, the fluid, which is refrigerant, is injected into the inlet branch channel 2111 of the base sear 11 from the water inlet channel 211 of the processing device 10. The fluid is further quickly branched into the inlets 113 of the heat exchange mechanism from the inlet branch channel 2111. The refrigerant is injected into the micro-channels 114 downward from the inlets 113. The micro-channels 114 are near the contact face 112. Heat exchange happens at the short micro-channels 114 densely arranged above the contact face 112 so that the heat consumption due to the flow length is reduced. Thus, the refrigerant of the micro-channels 114 can exchange heat quickly with the contact face 112 at the predetermined low temperature. In addition, plural heating wires 13 are arranged to control the temperature of the contact face 112 constant. The contact face 112 further controls the temperature of the electronic component 50 of the testing member 32 via the protection member 12 so as to test the electronic component 50 at the predetermined low temperature.

The heat-exchanged refrigerant from the micro-channels 114 of the heat exchange mechanism flows to the outlets 115 upward. The outlets 115 converge to the outlet branch channel 2121, and the heat-exchanged refrigerant further flows into the water outlet channel 212 from the outlet branch channel 2121 for discharging.

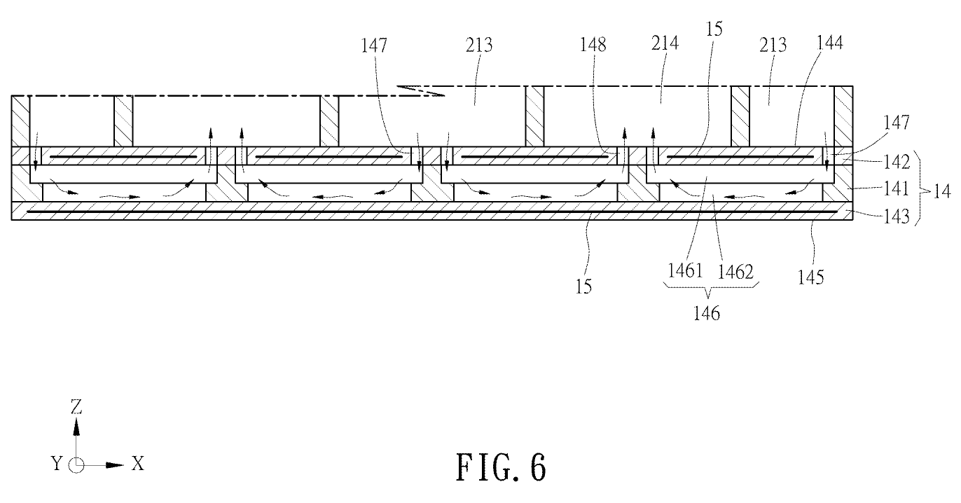

Please refer to FIG. 6, the second embodiment of the present invention has a similar design with the first embodiment. The difference is that the base seat 14 of the micro-channel unit includes a plurality of plates stacked together. The plates include a first plate 141, a second plate 142, and a third plate 143. The second plate 142 is stacked onto the first face of the first plate 141, and the first face of the second plate 142 is defined with an install face 144 to connect to at least one supporter or/and the fluid providing mechanism. The third plate 143 is stacked onto the second face of the first plate 141 upward. The third plate 143 is defined with a contact face 145 for connecting to an electronic component or at least one processing member (not shown in the drawings).

The base seat 14 is arranged with plural rows of micro-channels 146 penetrating the first face and the second face. Each of the micro-channels 146 has plural step-like layers of micro-sections. Thus, the flow can be increased without increasing the length of the micro-channel 146 so that the performance of heat exchange with the contact face is improved. In the present embodiment, the micro-channel 146 is arranged along the X-direction and has a length of 0.4 mm. The micro-channel 146 has a first micro-section 1461 and a second micro-section 1462 communicating with each other along the Z-direction. The first micro-section 1461 is near the second plate 142, and the second micro-section 1462 is near the third plate 143 and the contact face 145.

In the present embodiment, the second plate 142 of the base seat 14 is formed with a plurality of inlets 147. Each of the inlets 147 has a diameter of 0.2 mm and communicates the micro-channel 146 and the water inlet channel 213. The fluid is injected into the micro-channel 146 from the water inlet channel 213 via the inlet 147.

Specifically, the inlets 147 can communicate a single water inlet channel to provide the fluid, or the inlets 147 can communicate plural water inlet channels respectively. The present invention is not limited by the present embodiment.

Specifically, the inlets 147 can be arranged at the micro-channels 146, and the water inlet channel 213 communicates the inlets 147 from the peripheral side of the base seat 14.

In the present embodiment, the second plate 142 of the base seat 14 is arranged with plural outlets 148. Each of the outlets 148 has a diameter of 0.2 mm and communicates the micro-channel 146 and the water outlet channel 214. The heat- exchanged fluid from the micro-channel 146 enters the water outlet channel 214 via the outlets 148 for discharging.

Specifically, the outlets 148 can communicate a single water outlet channel to discharge the fluid, or the outlets 148 can communicate plural water inlet channels respectively. The present invention is not limited by the present embodiment.

The temperature unit has a temperature member, which is a heating wire 15, arranged on the second plate 142 and the third plate 143. The heat of the heating wire 15 corresponds to the temperature of the fluid to make the temperature of the contact face 145 at a predetermined temperature.

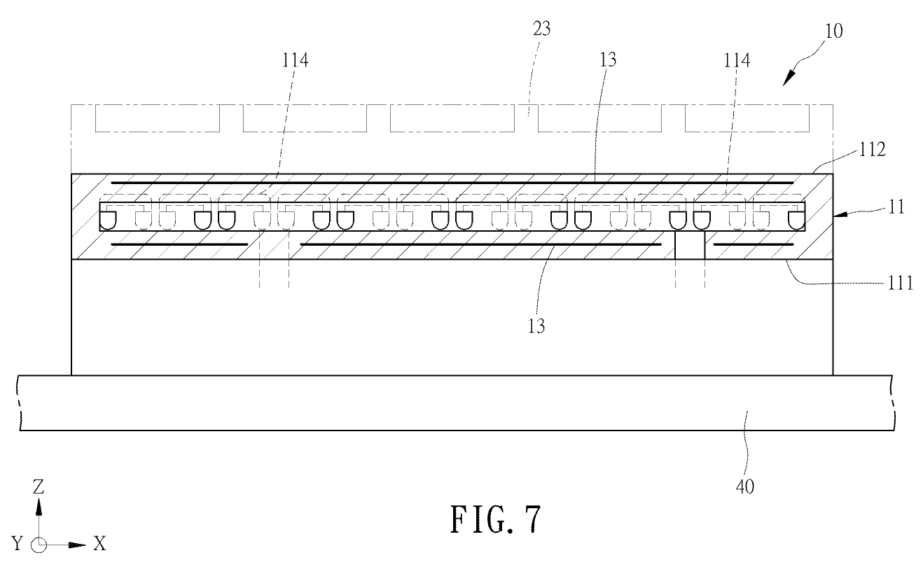

Please refer to FIG. 7 for the second embodiment of the processing device 10. The supporter is a machine platform 40. The install face 111 of the base seat 11 of the heat exchange mechanism is arranged on the machine platform via the fluid providing mechanism. The contact face 112 of the base seat 11 is adapted for connecting to a processing member which is a pre-heating platform 23. The micro-channels 114 of the micro-channel unit of the heat exchange mechanism corresponds to the heating wire 13 of the temperature unit to enable the heat exchange with the contact face 112 in plural micro-areas in order to make the temperature of the contact face constant and evenly. Thus, the temperatures of the pre-heating platform 23 and the electronic component (not shown in the drawings) are controlled quickly.

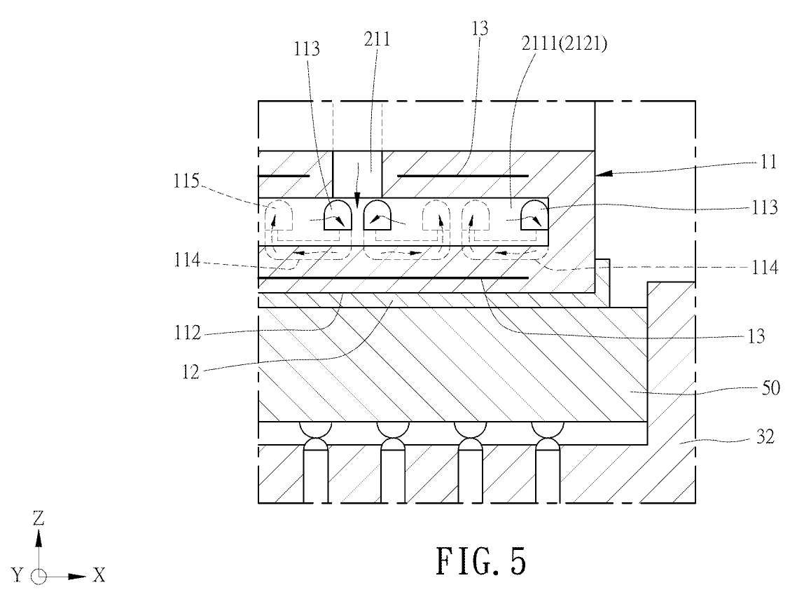

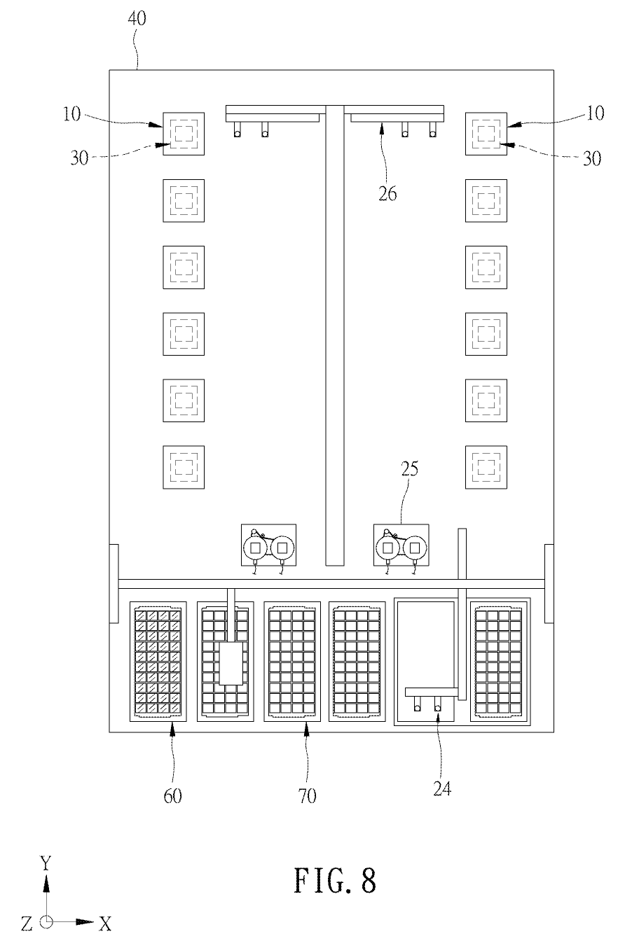

Please refer to FIG. 1 to FIG. 5 and FIG. 8, the electronic component processing machine with the processing device 10 includes a machine 40, a feeding device 60, a collecting device 70, the processing device 10, a testing device 30, and a central control device (not shown in the drawings). The feeding device 60 is arranged on the machine 40 and has at least one feeding member to receive at least one electronic component to be tested. The collecting device 70 is arranged on the machine 40 and has at least one collecting member to receive at least one tested electronic component. The testing device 30 is arranged on the machine 40 and has at least one testing member to test the electronic component. The at least one processing device 10 is arranged on the machine 40 and includes at least one supporter, at least one heat exchange mechanism, and at least one processing member. The processing device 10 further includes at least one transportation mechanism having at least transportation member to move the electronic component. In the present embodiment, the transportation mechanism has a first transportation member 24 to pick up the electronic component to be tested from the feeding member of the feeding device 60 to further move it to s second transportation member 25. The second transportation member 25 is adapted for a third transportation member 26 to pick up the electronic component. The third transportation member 26 moves the electronic component to be tested to the testing device for testing. The contact face 112 of the heat exchange mechanism of the processing device presses and contacts the electronic component and controls the temperature of the electronic component. The third transportation member 26 moves the tested electronic component to the second transportation member 25. The first transportation member 24 picks up the tested electronic component from the second transportation member 25 and sorts the electronic components by the results of testing. The sorted electronic components are received in the collecting member of the collecting device 70. The central control device (not shown in the drawings) is adapted for controlling and integrating the operation of the devices to achieve automatic process.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A heat exchange mechanism, including:
a micro-channel unit, arranged with a base seat having an install face and a contact face, the base seat having a plurality of inlets, a plurality of micro-channels, and a plurality of outlets, fluid flowing into the micro-channels from the inlets, the micro-channels being adapted for heat exchanging in plural micro-areas by the fluid and the contact faces, the heat-exchanged fluid being discharged from the outlets;
temperature unit, having at least one temperature member at the base seat or/and the micro-channels of the micro-channel unit, the temperature member and the fluid in the micro-channels making a temperature of the contact face constant.

2. The heat exchange mechanism of claim 1, wherein the base seat of the micro-channel unit is formed in a single piece.

3. The heat exchange mechanism of claim 1, wherein the base seat of the micro-channel unit is composed of a plurality of plates which are fixedly stacked together.

4. The heat exchange mechanism of claim 3, wherein the plates of the base seat includes a first plate and a second plate, a second face of the first plate is defined as the contact face, the micro-channels are formed in the first plate, the second plate is stacked onto the first plate, a first face of the second plate is defined as the install face, the inlets and the outlets are formed in the second plate.

5. The heat exchange mechanism of claim 4, wherein the at least one temperature member is arranged on one or plurals of the first plate, the second plate, and the micro-channels.

6. The heat exchange mechanism of claim 3, wherein the plates of the base seat includes a first plate, a second plate, and a third plate, the micro-channels are formed in the first plate and penetrates a first face and a second face of the first plate, a first face of the second plate is defined as the install face, a second face of the second plate is stacked onto the first face of the first plate, the inlets and the outlets are formed in the second plate, a second face of the third plate is defined as the contact face, and a first face of the third plate is stacked onto the second face of the first plate.

7. The heat exchange mechanism of claim 6, wherein the at least one temperature member is arranged on one or plurals of the second plate, the third plate, and the micro-channels.

8. The heat exchange mechanism of claim 1, wherein a height of the micro-channels is different from heights of the inlets and the outlets.

9. The heat exchange mechanism of claim 1, wherein a covering member covers the temperature member wherein the covering member is heat-conductive and electricity-insulating.

10. The heat exchange mechanism of claim 1, wherein at least one protection member is arranged on the contact face of the micro-channel unit.

11. A processing device, including:
at least one supporter;
at least one the heat exchange mechanism of claim 1, the install face being arranged on the supporter;
at least one processing member, arranged on the contact face of the base seat of the heat exchange mechanism or defined on the contact face, the processing member being adapted for undergo a predetermined process on an electronic component.

12. A processing machine, including:
a machine;
a feeding device, arranged on the machine, arranged with at least feeding member to receive an electronic component to be tested;
a collecting device, arranged on the machine, arranged with at least one collecting member to receive an tested electronic component;
a testing device, arranged on the machine, arranged with at least one testing member to test the electronic component to be tested;
at least one processing device of claim 11, arranged on the machine to undergo the predetermined process on the electronic component and control a temperature of the electronic component;
a central control device, controlling and integrating the devices to achieve an automatic process.
